(19) United States
(12) Patent Application Publication
(10) Pub. No.: US 2004/0216678 A1
(43) Pub. Date: Nov. 4, 2004

(54) Wafer Holder for Semiconductor Manufacturing Equipment and Semiconductor Manufacturing Equipment in Which It Is Installed

(75) Inventors: Masuhiro Natsuhara, Itami-shi (JP); Hirohiko Nakata, Itami-shi (JP); Manabu Hashikura, Itami-shi (JP)

Correspondence Address: JUDGE PATENT FIRM, RIVIERE SHUKUGAWA 3RD FL., 3-1 WAKAMATSU-CHO, NISHINOMIYA-SHI, HYOGO, 662-0035, JP

(73) Assignee: SUMITOMO ELECTRIC INDUSTRIES, LTD., Osaka-shi (JP)

(21) Appl. No.: 10/709,957

(22) Filed: Jun. 9, 2004

Related U.S. Application Data
(63) Continuation of application No. 10/604,132, filed on Jun. 27, 2003, now abandoned.

(30) Foreign Application Priority Data
Mar. 3, 2003 (JP) JP-2003-055061

(51) Int. Cl. C23C 16/00

(52) U.S. Cl. 118/728

(57) ABSTRACT

Wafer holder for semiconductor manufacturing and semiconductor manufacturing equipment in which the holder is installed, the wafer holder having a wafer-carrying surface, wherein the isothermal rating of its wafer-carrying surface is enhanced. In the wafer holder having a wafer-carrying surface, by making the diameter a of the wafer holder wafer-carrying surface not greater than the diameter b of the surface on its side opposite the wafer-carrying surface, the temperature distribution superficially in a wafer can be brought to within ±0.5%. Moreover, by making b−a ≧50 □m, the temperature distribution can be brought to within ±0.4%. The wafer holder is preferably a ceramic susceptor.

### BACKGROUND OF INVENTION

1. Field of the Invention

The present invention relates to wafer holders employed in semiconductor manufacturing equipment such as etching equipment, sputtering equipment, plasma CVD equipment, low-pressure plasma CVD equipment, metal CVD equipment, dielectric CVD equipment, low-k CVD equipment, MOCVD equipment, degassing equipment, ion-implantation equipment, and coater/developers, and furthermore to process chambers and semiconductor manufacturing equipment in which the wafer holders are installed.

2. Background Art

Conventionally, in semiconductor manufacturing procedures various processes such as film deposition processes and etching processes are carried out on semiconductor substrates (wafers) that are the processed objects. Ceramic susceptors that retain such semiconductor substrates in order to heat them are used in the semiconductor manufacturing equipment in which the processes on the semiconductor substrates are carried out.

Japanese Pat. App. Pub. No. H04-78138 for example discloses a conventional ceramic susceptor of this sort. The ceramic susceptor includes: a heater part made of ceramic, into which a resistive heating element is embedded and that is provided with a wafer-heating surface, arranged within a chamber; a columnar support part that is provided on a surface apart from the wafer-heating surface of the heating section and that forms a gastight seal between it and the chamber; and electrodes connected to the resistive heating element and leading outside the chamber so as essentially not to be exposed to the chamber interior space.

Although this invention serves to remedy the contamination and poor thermal efficiency that had been seen with heaters made of metal—heaters prior to the invention—it does not touch upon temperature distribution in semiconductor substrates being processed. Nonetheless, semiconductor-substrate temperature distribution is crucial in that it proves to be intimately related to yield in the situations where the aforementioned various processes are carried out. Given the importance of temperature distribution, Japanese Pat. App. Pub. No. 2001-118664, for example, discloses a ceramic susceptor capable of equalizing the temperature of the ceramic substrate. In terms of this invention, it is tolerable in practice that the temperature differential between the highest and lowest temperatures in the ceramic substrate surface be within in several %.

Scaling-up of semiconductor substrates has been moving forward in recent years, however. For example, with silicon (Si) wafers, a transition from 8-inch to 12-inch is in progress. Consequent on this diametric enlargement of the semiconductor substrate, that the temperature distribution in the heating surface (retaining surface) of semiconductor substrates on ceramic susceptors be within ±1.0% has become a necessity; that it be within ±0.5% has, moreover, become an expectation.

Also in recent years, accompanying the further microscopic scaling-down of the width of the circuit wiring lines formed onto wafers have been growing demands for thermal uniformity in the top-side temperature of wafers. An example is the wafer temperature distribution that has been called for in situations in which a photoresist film is spread onto a wafer by spin-coating or a like technique and is hardened, or the resist film is hardened after developing it—situations in which the wafer is heat-treated at, say, 200° C.: a temperature distribution of within ±0.3%, more preferably ±0.1%.

### SUMMARY OF INVENTION

The present invention has been brought about to address the foregoing issues. In particular, an object of the present invention is to realize for semiconductor manufacturing equipment a wafer holder with enhanced isothermal properties in its wafer-retaining surface, and semiconductor manufacturing equipment in which it is installed.

A semiconductor-manufacturing-equipment wafer holder according to the present invention is characterized in that the diameter a of the wafer holder wafer-carrying surface is not greater than the diameter b of the wafer holder surface on its side opposite the wafer-carrying surface. Moreover, the diameter b is preferably larger than the diameter a by 50 □m or more. Desirably, wafer holder is a ceramic susceptor interiorly in or superficially on which a resistive heating element is formed.

In semiconductor manufacturing equipment in which a wafer holder as in the foregoing is installed, the temperature of a wafer that is being processed proves to be more uniform than what has been conventional, making for better-yield manufacturing of semiconductors.

As defined by the present invention, making the diameter a of the wafer-carrying surface be less than or equal to the diameter b of the surface on the side opposite the wafer-carrying surface allows wafer holders and semiconductor manufacturing equipment of superlative temperature uniformity to be made available. What is more, the temperature uniformity can be enhanced further by rendering b−a≧50 □m. The fact that the wafer-holder temperature distribution in semiconductor manufacturing equipment in which a wafer holder of this sort is installed is more uniform than with conventional equipment serves to improve semiconductor characteristics and yields, as well as device reliability and integration level.

From the following detailed description in conjunction with the accompanying drawings, the foregoing and other objects, features, aspects and advantages of the present invention will become readily apparent to those skilled in the art.

### BRIEF DESCRIPTION OF DRAWINGS

FIG. 1 illustrates the sectional structure of a wafer holder according to the present invention wherein a<b;

FIG. 2 illustrates the sectional structure of a wafer holder according to the present invention wherein a=b;

FIG. 3 illustrates the sectional structure of a wafer holder according to the present invention wherein a>b;

FIG. 4 illustrates the sectional structure of another example of a wafer holder according to the present invention wherein a<b; and

FIG. 5 illustrates the sectional structure of still another example of a wafer holder according to the present invention wherein a<b.

### DETAILED DESCRIPTION

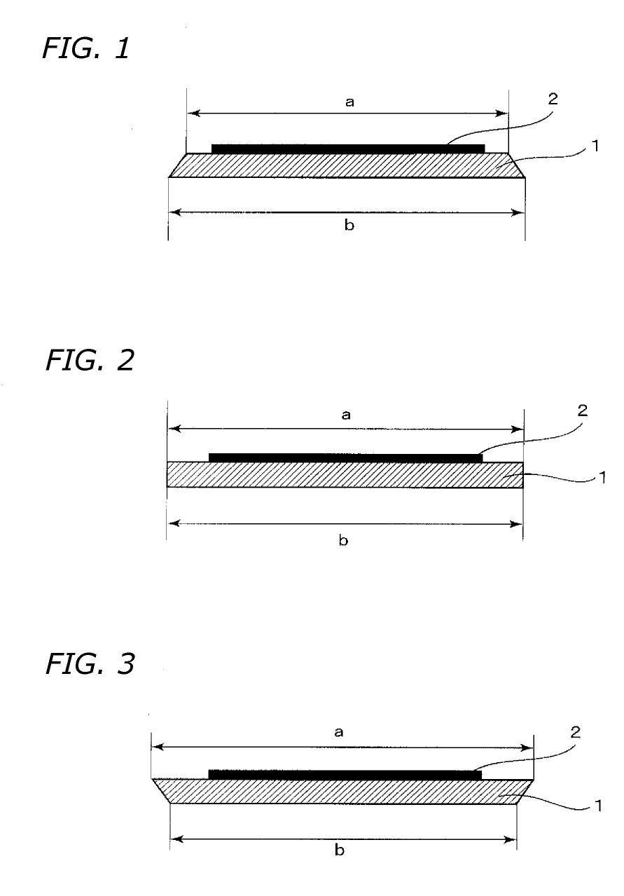

The present inventors discovered that in order to get the temperature distribution in the wafer-carrying surface to be within ±0.5%, the diameter a of the wafer-carrying surface of a wafer holder 1 as represented in FIG. 1 should be made less than or equal to the diameter b of the surface on the opposite side.

A wafer 2 undergoes predetermined processes with the wafer holder heating the wafer by means of a resistive heating element (not shown) formed either in the interior of the wafer holder, or else on a surface other than its wafer-carrying face. But it was discovered that if the wafer holder diameter a proves to be larger, as in FIG. 3, than its diameter b, the amount of heat that escapes from the peripheral margin of the wafer-carrying surface proves to be large, meaning that temperature distribution in the wafer-carrying surface is liable to be non-uniform. The fact the temperature of the wafer being carried will drop sporadically if the temperature of the wafer-carrying face drops sporadically will for example create fluctuations in the thickness and properties of films formed when a film-forming process is conducted on the wafer. In etching processes, for example, fluctuations in etching speed will be produced.

This is why as slight as possible a temperature distribution in the wafer-carrying surface—currently, an isothermal rating of within ±1.0%, with expectations for an isothermal rating of within ±0.5% likely—is being sought. It was discovered that in order to gain an isothermal rating along these lines, the diameter a should, as indicated in FIG. 1 or FIG. 2, be not greater than the diameter b.

The heat generated by the ceramic susceptor not only heats the wafer-carrying surface but also diffuses to surfaces other than the wafer-carrying face. It was discovered that under the circumstances, in cases where the diameter a of the wafer-carrying surface is larger than the diameter b of the surface on the side opposite, as shown in FIG. 3, the temperature distribution in the wafer-carrying surface will be large, while in the FIG. 1 (a<b) or FIG. 2 (a=b) cases the temperature distribution in the wafer-carrying surface proves to be better, enhancing the isothermal properties of the wafer-carrying surface and consequently enhancing the isothermal properties of the surface of a wafer set onto the wafer-carrying surface.

Although in a wafer holder, with the heat radiant from the side face being considerable, the temperature of a wafer periphery tends to drop, by making the diameter of the wafer-carrying surface relatively smaller than the diameter of the surface on the side opposite it, the surface area of the radiant heat can be lessened such that the temperature distribution in the wafer-carrying surface can be made more uniform. In particular, in the periphery of the wafer-carrying surface because it is in the location whose distance is furthest from resistive heating element and is where the radiant-heat surface area is greatest, there is a tendency for the temperature to drop easily. Therefore, the isothermal rating can be made better by bringing closer the separation of the outer periphery from the heating element, and by lessening the radiant surface area.

If the superficial temperature distribution in a wafer is to be brought within an isothermal rating of ±0.5%, a≦b should hold. Furthermore, the diameter b is preferably made larger than the diameter a by 50 □m or more, i.e., b−a≧50 □m is made to hold, because the temperature distribution in the wafer-carrying surface can be brought to within an isothermal rating of ±0.4% or less.

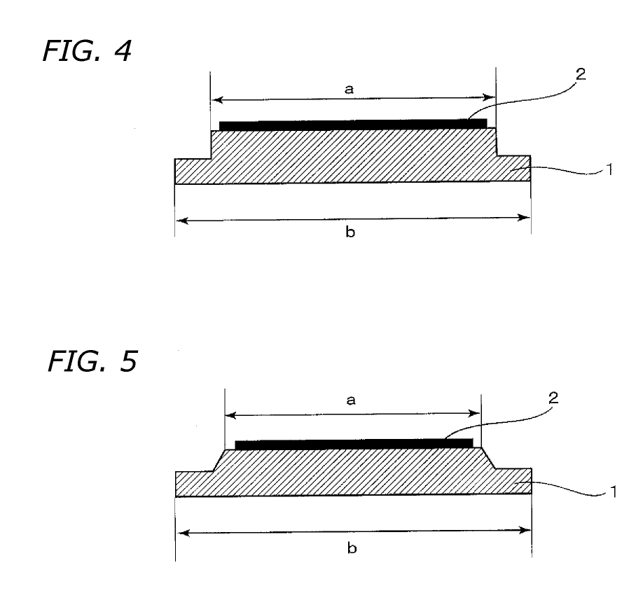

In order to produce a difference between diameter b and diameter a, other than by the technique indicated in FIG. 1, temperature uniformity can be improved by providing an offset in the wafer holder as illustrated in FIG. 4. By the same token, further forming a slope as indicated in FIG. 5 in the offset in the wafer-holder lateral surface is also possible; there are not particular limitations as to the shape as long as diameter b is longer than diameter a.

The shape of the lateral surface of the wafer holder, and the difference between diameter b and diameter a, as set forth in the foregoing should be selected appropriately according to the required temperature uniformity, to cost requirements, and also to the configuration of the equipment in which the holder is installed. Nevertheless, it is necessary that the diameter a of the wafer-carrying surface be greater in extent by 5 mm or more than the diameter of the wafers that the holder carries. It would be disadvantageous for the diameter a to be less than this in extent, because then the drop in temperature in the wafer-holder periphery would have an impact on the temperature distribution and contrarily the temperature uniformity would degrade.

Ceramics are preferable as the substance for a wafer holder according to the present invention. Metals would be undesirable since a problem with employing them is that particles cling onto the wafers. High-thermal-conductivity aluminum nitride and silicon carbide are preferable as ceramics if stress is to be placed on uniformity in temperature distribution. If stress is to be placed on dependability, silicon nitride, being high-strength and tough against thermal shock, is preferable. If cost is to be emphasized, then aluminum oxide is preferable.

Among these ceramics, if a performance-cost balance is taken into consideration, aluminum nitride (AIN), with its high thermal conductivity and superior resistance to corrosion, is ideally suitable. In the following, a method by the present invention of manufacturing a wafer holder in an AIN instance will be described in detail.

An AIN raw-material powder whose specific surface area is 2.0 to 5.0 m²/g is preferable. The sinterability of the aluminum nitride declines if the specific surface area is less than 2.0 m²/g. Handling proves to be a problem if on the other hand the specific surface area is over 5.0 m²/g, because the powder coherence becomes extremely strong. Furthermore, the quantity of oxygen contained in the raw-material powder is preferably 2 wt. % or less. In sintered form, its thermal conductivity deteriorates if the oxygen quantity is in excess of 2 wt. %. It is also preferable that the amount of metal impurities contained in the raw-material powder other than aluminum be 2000 ppm or less. The thermal conductivity of the powder in sintered form deteriorates if the amount of metal impurities exceeds this range. In particular, the content respectively of Group IV elements such as Si, and elements of the iron family, such as Fe, which have a serious worsening effect on the thermal conductivity of the sinter, is advisably 500 ppm or less.

Because AIN is not a readily sinterable material, adding a sintering promoter to the AIN raw-material powder is advisable. The sintering promoter added preferably is a rare-earth element compound. Since rare-earth element compounds react with aluminum oxides or aluminum oxynitrides present on the surface of the particles of the aluminum nitride powder, acting to promote densification of the aluminum nitride and to eliminate oxygen being a causative factor that worsens the thermal conductivity of an aluminum nitride sinter, they enable the thermal conductivity of aluminum sinters to be improved.

Yttrium compounds, whose oxygen-eliminating action is particularly pronounced, are preferable rare-earth element compounds. The amount added is preferably 0.01 to 5 wt. %. If less than 0.01 wt. %, producing ultrafine sinters is problematic, along with which the thermal conductivity of the sinters deteriorates. Added amounts in excess of 5 wt. % on the other hand lead to sintering promoter being present at the grain boundaries in an aluminum nitride sinter, and consequently, if the aluminum nitride sinter is employed under a corrosive atmosphere, the sintering promoter present along the grain boundaries gets etched, becoming a source of loosened grains and particles. More preferably the amount of sintering promoter added is 1 wt. % or less. If less than 1 wt. % sintering promoter will no longer be present even at the grain boundary triple points, which improves the corrosion resistance.

To characterize the rare-earth compounds further: oxides, nitrides, fluorides, and stearic oxide compounds may be employed. Among these oxides, being inexpensive and readily obtainable, are preferable. By the same token, stearic oxide compounds are especially suitable since they have a high affinity for organic solvents, and if the aluminum nitride raw-material powder, sintering promoter, etc. are to be mixed together in an organic solvent, the fact that the sintering promoter is a stearic oxide compound will heighten the miscibility.

Next, the aluminum nitride raw-material powder, sintering promoter as a powder, a predetermined volume of solvent, a binder, and further, a dispersing agent or a coalescing agent added as needed, are mixed together. Possible mixing techniques include ball-mill mixing and mixing by ultrasound. Mixing can thus produce a raw material slurry.

The obtained slurry can be molded, and by sintering the molded product, an aluminum nitride sinter can be produced. Co-firing and post-metallization are two possible methods as a way of doing this.

Post-metallization will be described first. Granules are prepared from the slurry by means of a technique such as spray-drying. The granules are inserted into a predetermined mold and subject to press-molding. The pressing pressure therein desirably is 9.8 MPa or more. With pressure less than 9.8 MPa, in most cases sufficient strength in the molded mass cannot be produced, making it liable to break in handling.

Although the density of the molded mass will differ depending on the amount of binder contained and on the amount of sintering promoter added, preferably it is 1.5 g/cm³ or more. Densities less than 1.5 g/cm³ would mean a relatively large distance between particles in the raw-material powder, which would hinder the progress of the sintering. At the same time, the molded mass density preferably is 2.5 g/cm³ or less. Densities of more than 2.5 g/cm³ would make it difficult to eliminate sufficiently the binder from within the molded mass in a degreasing process of a subsequent step. It would consequently prove difficult to produce an ultrafine sinter as described earlier.

Next, heating and degreasing processes are carried out on the molded mass within a non-oxidizing atmosphere. Carrying out the degreasing process under an oxidizing atmosphere such as air would degrade the thermal conductivity of the sinter, because the AIN powder would become superficially oxidized. Preferable non-oxidizing ambient gases are nitrogen and argon. The heating temperature in the degreasing process is preferably 500° C. or more and 1000° C. or less. With temperatures of less than 500° C., surplus carbon is left remaining within the laminate following the degreasing process because the binder cannot sufficiently be eliminated, which interferes with sintering in the subsequent sintering step. On the other hand, at temperatures of more than 1000° C., the ability to eliminate oxygen from the oxidized coating superficially present on the surface of the AIN powder deteriorates, such that the amount of carbon left remaining is too little, degrading the thermal conductivity of the sinter.

The amount of carbon left remaining within the molded mass after the degreasing process is preferably 1.0 wt. % or less. If carbon in excess of 1.0 wt. % remains, it will interfere with the sintering, which would mean that ultrafine sinters could not be produced.

Next, sintering is carried out. The sintering is carried out within a non-oxidizing nitrogen, argon, or like atmo- sphere, at a temperature of 1700 to 2000° C. Therein the moisture contained in the ambient gas such as nitrogen that is employed is preferably −30° C. or less given in dew point. If it were to contain more moisture than this, the thermal conductivity of the sinter would likely be degraded, because the AIN would react with the moisture within the ambient gas during sintering and form nitrides. Another preferable condition is that the volume of oxygen within the ambient gas be 0.001 vol. % or less. A larger volume of oxygen would lead to a likelihood that the AIN would oxidize, impairing the sinter thermal conductivity.

As another condition during sintering, the jig employed is suitably a boron nitride (BN) molded part. Inasmuch as the jig as a BN molded part will be sufficiently heat resistant against the sintering temperatures, and superficially will have solid lubricity, when the laminate contracts during sintering, friction between the jig and the laminate will be lessened, which will enable sinters to be produced with little distortion.

The obtained sinter is subjected to processing according to requirements. In cases where a conductive paste is to be screen-printed onto the sinter in a succeeding step, the surface roughness is preferably 5 □m or less in Ra. If over 5 □m, in screen printing to form circuits, defects such as blotting or pinholes in the pattern are liable to arise. More suitable is a surface roughness of 1 □m or less in Ra.

In polishing to the abovementioned surface roughness, although cases in which both sides of the sinter are screen printed are a matter of course, even in cases where screen printing is effected on one side only the polishing process is best carried out on the face on the side opposite the screen-printing face. This is because polishing only the screen-printing face would mean that during screen printing, the sinter would be supported on the unpolished face, and in that situation burrs and debris would be present on the unpolished face, destabilizing the fixedness of the sinter such that the circuit pattern by the screen printing might not be drawn well.

Furthermore, at this point the thickness uniformity (parallelism) between the processed faces is preferably 0.5 mm or less. Thickness uniformity exceeding 0.5 mm can lead to large fluctuations in the thickness of the conductive paste during screen printing. Particularly suitable is a thickness uniformity of 0.1 mm or less. Another preferable condition is that the planarity of the screen-printing face be 0.5 mm or less. If the planarity exceeds 0.5 mm, in that case too there can be large fluctuations in the thickness of the conductive paste during screen printing. Particularly suitable is a planarity of 0.1 mm or less.

Screen printing is used to spread a conductive paste and form the electrical circuits onto a sinter having undergone the polishing process. The conductive paste can be obtained by mixing together with a metal powder an oxidized powder, a binder, and a solvent according to requirements. The metal powder is preferably tungsten, molybdenum or tantalum, since their thermal expansion coefficients match those of ceramics.

Adding the oxidized powder to the conductive paste is also to enhance the strength with which it bonds to AIN. The oxidized powder preferably is an oxide of Group ha or Group Ilia elements, or is Al₂O₃, SiO₂, or a like oxide. Yttrium oxide is especially preferable because it has very good wettability with AIN. The amount of such oxides added is preferably 0.1 to 30 wt. %. If the amount is less than 0.1 wt. %, the bonding strength between AIN and the metal layer being the circuit that has been formed deteriorates. On the other hand, amounts in excess of 30 wt. % make the electrical resistance of the circuit metal layer high.

The thickness of the conductive paste is preferably 5 □m or more and 100 □m or less in terms of its post-drying thickness. If the thickness were less than 5 □m the electrical resistance would be too high and the bonding strength decline. Likewise, if in excess of 100 □m the bonding strength would deteriorate in that case too.

Also preferable is that in the patterns for the circuits that are formed, in the case of the heater circuit (resistive heating element circuit), the pattern spacing be 0.1 mm or more. With a spacing of less than 0.1 mm, shorting will occur when current flows in the resistive heating element and, depending on the applied voltage and the temperature, leakage current is generated. Particularly in cases where the circuit is employed at temperatures of 500° C. or more, the pattern spacing preferably should be 1 mm or more; more preferable still is that it be 3 mm or more.

After the conductive paste is degreased, baking follows. Degreasing is carried out within a non-oxidizing nitrogen, argon, or like atmosphere. The degreasing temperature is preferably 500° C. or more. At less than 500° C., elimination of the binder from the conductive paste is inadequate, leaving behind carbon in the metal layer that during baking will form carbides with the metal and consequently raise the electrical resistance of the metal layer.

The baking is suitably done within a non-oxidizing nitrogen, argon, or like atmosphere at a temperature of 1500° C. or more. At temperatures of less than 1500° C., the post-baking electrical resistance of the metal layer turns out too high because the baking of the metal powder within the paste does not proceed to the grain growth stage. A further baking parameter is that the baking temperature should not surpass the firing temperature of the ceramic produced. If the conductive paste is baked at a temperature beyond the firing temperature of the ceramic, dispersive volatilization of the sintering promoter incorporated within the ceramic sets in, and moreover, grain growth in the metal powder within the conductive paste is accelerated, impairing the bonding strength between the ceramic and the metal layer.

In order to ensure that the metal layer is electrically isolated, an insulative coating can be formed on the metal layer. The insulative coating substance is not particularly limited as long as its reactivity with the electrical circuits is low and its difference in thermal conductivity with AIN is 5.0×10⁻⁶ or less. Substances that may be employed include glass-ceramic or AIN, for example. These materials may be worked by, for example, rendering them into paste form, screen-printing the paste to a predetermined thickness and, after degreasing printed paste as may be necessary, baking it at a predetermined temperature.

In that case, the amount of sintering promoter added preferably is 0.01 wt. % or more. With an amount less than 0.01 wt. % the insulative coating does not densify, making it difficult to secure electrical isolation of the metal layer. It is further preferable that the amount of sintering promoter not exceed 20 wt. %. Surpassing 30 wt. % leads to excess sintering promoter invading the metal layer, which can end up altering the metal-layer electrical resistance. Although not particularly limited, the spreading thickness preferably is 5 □m or more. This is because securing electrical isolation proves to be problematic at less than 5 □m.

As far as materials for the conductive paste are concerned, mixtures or alloys of metals such as silver, palladium and platinum can be employed. With these metals, inasmuch as the volume resistivity of a conductor is increased by adding palladium or platinum to silver content, an amount added should be adjusted depending on the circuit pattern. Likewise, inasmuch as these additives are effective for preventing electromigration between circuit patterns, adding 0.1 or more parts by weight to 100 parts by weight silver is advantageous.

Adding metal oxides to powders of these metals is advisable in order to ensure the bondability of the metals with AIN. Oxides that may be added include, for example, aluminum oxide, silicon oxide, copper oxide, boron oxide, zinc oxide, lead oxide, rare earth oxides, transition metal group oxides, and alkaline earth metal oxides. Preferable as the amount added is 0.1 wt. % or more but 50 wt. % or less. Content less than this range would be undesirable because the bondability with aluminum nitride would deteriorate. Likewise, content greater than this range would be disadvantageous because it would interfere with sintering of the metal components such as silver.

The circuits may be formed by mixing powders of these metals with powdered inorganic substances, then adding an organic solvent and a binder, rendering the mixture into paste form, and screen printing the paste in the manner noted above. Baking circuit patterns formed in this case is within a nitrogen or like inert gas atmosphere, or else within air, at a temperature in a range of from 700° C. to 1000° C.

In this case furthermore, in order to ensure electrical isolation between circuits, an insulating layer may be formed by coating on a material such as glass-ceramic, glass glaze, or an organic resin, and baking or else curing the material. The types of glass that may be employed include boron silicate glass, lead oxide, zinc oxide, aluminum oxide, and silicon oxide. Into powders of these an organic solvent and a binder are added, the combination is rendered into paste form, and the paste is screen-printed to coat it on. Although the coating thickness is not particularly restricted, preferably it is 5 □m or more. This is because securing insulating properties proves to be problematic at less than 5 □m. Furthermore, the baking temperature preferably is lower than the temperature when forming the circuits described above. Baking at a temperature higher than that during the aforementioned circuit baking would be undesirable because the resistance of the circuit patterns would be altered significantly.

Further according to the present method, the ceramic as substrates can be laminated according to requirements. Lamination may be done via a bonding agent. The bonding agent—being is a compound of Group IIa or Group IIIa elements, and a binder and solvent, added to an aluminum oxide powder or aluminum nitride powder and made into a paste—is spread onto the bonding surface by a technique such as screen printing. The thickness of the applied bonding agent is not particularly restricted, but preferably is 5 □m or more. Bonding defects such as pin-holes and bonding irregularities are liable to arise in the bonding layer with thicknesses of less than 5 □m.

The ceramic substrates onto which the bonding agent has been spread are degreased within a non-oxidizing atmosphere at a temperature of 500° C. or more. The ceramic substrates are thereafter bonded to one another by stacking the ceramic substrates together, applying a predetermined load to the stack, and heating it within a non-oxidizing atmosphere. The load preferably is 5 kPa or more. With loads of less than 5 kPa sufficient bonding strength will not be obtained, and otherwise defects in the bond will likely occur.

Although the heating temperature for bonding is not particularly restricted as long as it is a temperature at which the ceramic substrates adequately bond to one another via the bonding layers, preferably it is 1500° C. or more. At less than 1500° C. adequate bonding strength proves difficult to gain, such that defects in the bond are liable to arise. Nitrogen or argon is preferably employed for the non-oxidizing atmosphere during the degreasing and boding just discussed.

A ceramic sinter laminate that serves as a wafer holder thus can be produced as in the foregoing. As far as the electrical circuits are concerned, it should be understood that if they are heater circuits for example, then a molybdenum coil can be utilized, and in the electrostatic—chuck electrode and RF electrode cases, molybdenum or tungsten mesh can be, without employing conductive paste.

In this case, the molybdenum coil or the mesh can be built into the AIN raw-material powder, and the wafer holder can be fabricated by hot pressing. While the temperature and atmosphere in the hot press may be on par with the AIN sintering temperature and atmosphere, the hot press desirably applies a pressure of 0.98 MPa or more. With pressure of less than 0.98 MPa, the wafer holder might not exhibit its capabilities, because gaps arise between the AIN and the molybdenum coil or the mesh.

Co-firing will now be described. The earlier-described raw-material slurry is molded into a sheet by doctor blading. The sheet-molding parameters are not particularly limited, but the post-drying thickness of the sheet advisably is 3 mm or less. The sheet thickness surpassing 3 mm leads to large shrinkage in the drying slurry, raising the probability that fissures will be generated in the sheet.

A metal layer of predetermined form that serves as an electrical circuit is formed onto the abovementioned sheet using a technique such as screen printing to spread onto it a conductive paste. The conductive paste utilized can be the same as that which was descried under the post-metallization method. Nevertheless, not adding an oxidized powder to the conductive paste does not hinder the co-firing method.

Subsequently, sheets that have undergone circuit formation are laminated with sheets that have not. Lamination is by setting the sheets each into position to stack them together. Therein, according to requirements, a solvent is spread on between sheets. In the stacked state, the sheets are heated as may be necessary. In cases where the stack is heated, the heating temperature is preferably 150° C. or less. Heating to temperatures in excess of this greatly deforms the laminated sheets. Pressure is then applied to the stacked-together sheets to unitize them. The applied pressure is preferably within a range of from 1 to 100 MPa. At pressures less than 1 MPa, the sheets are not adequately unitized and can peel apart during subsequent processes. Likewise, if pressure in excess of 100 MPa is applied, the extent to which the sheets deform becomes too great.

This laminate undergoes a degreasing process as well as sintering, in the same way was with the post-metallization method described earlier. Parameters such as the temperature in degreasing and sintering and the amount of carbon are the same as with post-metallization. In the previously described screen printing of a conductive paste onto sheets, a wafer holder having a plurality of electrical circuits can be readily fabricated by printing heater circuits, electrostatic-chuck electrodes, etc. respectively onto a plurality of sheets and laminating them. In this way a ceramic laminated sinter that serves as a wafer holder can be produced.

It will be appreciated that in cases in which an electrical circuit such as a heating element circuit is formed on the outermost layer of the ceramic laminate, an insulative coating can be formed onto the circuit likewise as with the afore-described post-metallization method in order to protect the electrical circuit and to ensure it is electrically isolated.

The obtained ceramic laminated sinter is subject to processing according to requirements. Routinely with semiconductor manufacturing equipment, in the sintered state the ceramic laminated sinter often cannot be gotten into the precision demanded. The planarity of the wafer-carrying face as an example of processing precision is preferably 0.5 mm or less; moreover 0.1 mm or less is particularly preferable. The planarity surpassing 0.5 mm is apt to give rise to gaps between the wafer and the wafer holder, keeping the heat of the wafer holder from being uniformly transmitted to the wafer and making likely the generation of temperature irregularities in the wafer.

A further preferable condition is that the surface roughness of the wafer-carrying face be 5 □m in Ra. If the roughness is over 5 □m in Ra, grains loosened from the AIN due to friction between the wafer holder and the wafer can grow numerous. Particles loosened in that case become contaminants that have a negative effect on processes, such as film deposition and etching, on the wafer.

Furthermore, then, a surface roughness of 1 □m or less in Ra is ideal.

A wafer holder base part can thus be fabricated as in the foregoing. A shaft may be attached to the wafer holder as needed. Although the shaft substance is not particularly limited as long as its thermal expansion coefficient is not appreciably different from that of the wafer-holder ceramic, the difference in thermal expansion coefficient between the shaft substance and the wafer holder preferably is 5×10⁻⁶ K or less.

If the difference in thermal expansion coefficient exceeds 5×10⁻⁶ K, cracks can arise adjacent the joint between the wafer holder and the shaft when it is being attached;

but even if cracks do not arise when the two are joined, splitting and cracking can occur in the joint in that it is put through heating cycling in the course of being repeatedly used. For cases in which the wafer holder is AIN, for example, the shaft substance is optimally AIN; but silicon nitride, silicon carbide, or mullite can be used.

Mounting is joining via an adhesive layer. The adhesive layer constituents preferably are composed of AIN and Al ₂O₃, as well as rare-earth oxides. These constituents are preferable because of their favorable wettability with ceramics such as the AIN that is the substance of the wafer holder and the shaft, which makes the joint strength relatively high, and readily produces a gastight joint surface.

The planarity of the respective joining faces of the shaft and wafer holder to be joined preferably is 0.5 mm or less. Planarity greater than this makes gaps liable to occur in the joining faces, impeding the production of a joint having adequate gastightness. A planarity of 0.1 mm or less is more suitable. Here, still more suitable is a planarity of the wafer holder joining faces of 0.02 mm or less. Likewise, the surface of the respective joining faces preferably is 5 □m or less in Ra. Surface roughness exceeding this would then also mean that gaps are liable to occur in the joining faces. A surface roughness of 1 □m or less in Ra is still more suitable.

Subsequently, electrodes are attached to the wafer holder. The attaching can be done according to publicly known techniques. For example, the side of the wafer holder opposite its wafer-carrying surface, may be spot faced through to the electrical circuits, and metallization carried out on the circuit, or without metallizing, electrodes of molybdenum, tungsten, etc. may be connected to it directly using activated metal solder. The electrodes can thereafter be plated as needed to improve their resistance to oxidation. In this way, a wafer holder for semiconductor manufacturing equipment can be fabricated.

Moreover, semiconductor wafers can be processed on a wafer holder according to the present invention, integrated into semiconductor manufacturing equipment. Inasmuch as the temperature of the wafer-carrying surface of a wafer holder by the present invention is uniform, the temperature distribution in the wafer will be more uniform than is conventional, to yield stabilized characteristics in terms of deposited films, heating processes, etc.

### EMBODIMENTS

Embodiment 1—99 parts by weight aluminum nitride powder and 1 part by weight Y₂O₃ powder were mixed and blended with 10 parts by weight polyvinyl butyral as a binder and 5 parts by weight dibutyl phthalate as a solvent, and doctor-bladed into a green sheet 430 mm in diameter and 1.0 mm in thickness. Here, an aluminum nitride powder having a mean particle diameter of 0.6 □m and a specific surface area of 3.4 m²/g was utilized. In addition, a tungsten paste was prepared utilizing 100 parts by weight of a tungsten powder whose mean particle diameter was 2.0 □m; and per that, 1 part by weight Y₂O₃ and 5 parts by weight ethyl cellulose, being a binder; and butyl Carbitol™ as a solvent. A pot mill and a triple-roller mill were used for mixing. This tungsten paste was formed into a heater circuit pattern by screen-printing onto the green sheet.

Pluralities of separate green sheets of thickness 1.0 mm were laminated onto the green sheet printed with the heater circuit to create laminates. Lamination was carried out by stacking the sheets in place in a mold, and thermopressing 2 minutes in a press at a pressure of 10 MPa while maintaining 50° C. heat. The laminates were thereafter degreased within a nitrogen atmosphere at 600° C., and sintered within a nitrogen atmosphere under time and temperature conditions of 3 hours and 1800° C., whereby wafer holders were produced. Here, a polishing process was performed on the wafer-carrying surface so that it would be 1 □m or less in Ra, and on the shaft-joining face so that it would be 5 □m or less in Ra. The wafer holders were also processed to true their outer diameter. The dimensions of post-processing wafer holders are given in the table below. The thickness of the wafer holders was 20 mm.

The heater circuits in the wafer holders were partially exposed by spot-facing through the surface on the side opposite the wafer-carrying surface, up to the heater circuit. Electrodes made of molybdenum were connected directly to the exposed portions of the heater circuits utilizing an active metal brazing material. The wafer holders were hated by passing current through the electrodes, and their isothermal ratings were measured.

Measurement of isothermal ratings was by setting a temperature-measuring instrument 300 mm in diameter on the wafer-carrying surfaces and measuring their temperature distributions. It should be understood that the power supply was adjusted to that the temperature in the mid-portion of the temperature-measuring instrument would 550° C. The results are set forth in Table I.

TABLE I

| | | | | Isothermal |
|---|---|---|---|---|
| No. | Diameter a(mm) | Diameter b(mm) | b − a(□m) | rating (%) |
| 1 | 340.20 | 340.00 | −200 | ±0.60 |
| 2 | 340.15 | 340.00 | −150 | ±0.59 |
| 3 | 340.12 | 340.00 | −120 | ±0.58 |
| 4 | 340.10 | 340.00 | −100 | ±0.57 |
| 5 | 340.07 | 340.00 | −70 | ±0.55 |
| 6 | 340.06 | 340.00 | −60 | ±0.54 |
| 7 | 340.04 | 340.00 | −40 | ±0.53 |
| 8 | 340.02 | 340.00 | −20 | ±0.51 |
| 9 | 340.00 | 340.00 | 0 | ±0.50 |
| 10 | 339.98 | 340.00 | 20 | ±0.46 |
| 11 | 339.97 | 340.00 | 30 | ±0.43 |
| 12 | 339.95 | 340.00 | 50 | ±0.40 |
| 13 | 339.93 | 340.00 | 70 | ±0.38 |
| 14 | 339.90 | 340.00 | 100 | ±0.37 |
| 15 | 339.85 | 340.00 | 150 | ±0.35 |
| 16 | 339.80 | 340.00 | 200 | ±0.33 |
| 17 | 339.50 | 340.00 | 0.5 | ±0.32 |
| 18 | 339.00 | 340.00 | 1.0 | ±0.30 |
| 19 | 338.00 | 340.00 | 2.0 | ±0.28 |
| 20 | 337.00 | 340.00 | 3.0 | ±0.26 |
| 21 | 336.00 | 340.00 | 4.0 | ±0.24 |
| 22 | 335.00 | 340.00 | 5.0 | ±0.23 |
| 23 | 330.00 | 340.00 | 10.0 | ±0.20 |
| 24 | 325.00 | 340.00 | 15.0 | ±0.17 |
| 25 | 320.00 | 340.00 | 20.0 | ±0.15 |
| 26 | 310.00 | 340.00 | 30.0 | ±0.13 |
| 27 | 305.00 | 340.00 | 35.0 | ±0.28 |
| 28 | 300.00 | 340.00 | 40.0 | ±1.40 |

As is evident from Table I, by making the diameter b the diameter a or greater, the temperature distribution in the wafer-carrying surface could be brought within ±0.5%. What is more, making the diameter b larger than the diameter a by 50 □m or more can bring the temperature distribution in the wafer-carrying surface within ±0.4%.

Embodiment 2—The wafer holders of the table were assembled into semiconductor manufacturing equipment, wherein TiN films were formed onto silicon wafers 12 inches in diameter. In cases in which wafer holders Nos. 1 through 8 were used, fluctuations in the TiN film thickness were a large 15% or more; but being that in cases in which the wafer holders other than these were utilized, fluctuations in the film thickness were a small 10% or less, excellent TiN films could be formed.

Embodiment 3—Wafer holders of 20 mm thickness were fabricated likewise as with Embodiment 1. An offset as represented in FIG. 4 was formed in the wafer holders, and the temperature uniformity (isothermal rating) was measured by the same technique as in Embodiment 1. The results are set forth in Table II.

TABLE II

| | | | | Isothermal |
|---|---|---|---|---|
| No. | Diameter a(mm) | Diameter b(mm) | b − a(mm) | rating (%) |
| 29 | 338.00 | 340.00 | 2.0 | ±0.27 |
| 30 | 335.00 | 340.00 | 5.0 | ±0.22 |
| 31 | 330.00 | 340.00 | 10.0 | ±0.20 |
| 32 | 325.00 | 340.00 | 15.0 | ±0.16 |
| 33 | 320.00 | 340.00 | 20.0 | ±0.15 |
| 34 | 310.00 | 340.00 | 30.0 | ±0.13 |
| 35 | 305.00 | 340.00 | 35.0 | ±0.33 |
| 36 | 300.00 | 340.00 | 40.0 | ±1.40 |

As will be understood from the table, also in examples in which an offset was formed, by making the diameter b the diameter a or greater, the temperature distribution in the wafer-carrying surface could be brought within ±0.5%. What is more, making the diameter b larger than the diameter a by 50 □m or more can bring the temperature distribution in the wafer-carrying surface within ±0.4%.

According to the present invention, making the diameter a of the wafer-carrying surface not greater than the diameter b of the surface on the side opposite the wafer-carrying surface, makes it possible to provide wafer holders and semiconductor manufacturing equipment of superior isothermal rating. Making b−a≧50 □m renders it possible to enhance the isothermal rating further. The fact that heater temperature distribution in semiconductor manufacturing equipment in which a wafer holder of this sort is installed proves to be more uniform than with conventional equipment serves to improve semiconductor characteristics and yields, as well as device reliability and integration level.

What is claimed is:

1. A wafer holder for semiconductor manufacturing equipment, the wafer holder having a wafer-carrying surface and characterized in that the diameter a of the wafer holder wafer-carrying surface is not greater than the diameter b of the wafer holder surface on its side opposite the wafer-carrying surface.

2. The wafer holder set forth in claim 1, wherein the diameter b is larger than the diameter a by 50 □m or more.

3. The wafer holder set forth in claim 1, being a ceramic susceptor interiorly in or superficially on which a resistive heating element is formed.

4. The wafer holder set forth in claim 2, being a ceramic susceptor interiorly in or superficially on which a resistive heating element is formed.

5. Semiconductor manufacturing equipment wherein the wafer holder set forth in claim 1 is installed.

6. Semiconductor manufacturing equipment wherein the wafer holder set forth in claim 2 is installed.

7. Semiconductor manufacturing equipment wherein the wafer holder set forth in claim 3 is installed.

8. Semiconductor manufacturing equipment wherein the wafer holder set forth in claim 4 is installed.
